(19) United States
(12) Patent Application Publication
(10) Pub. No.: US 2012/0218753 A1
(43) Pub. Date: Aug. 30, 2012

(54) ELECTRONIC DISPLAY

(75) Inventors: Brent A. Joffer, Brookings, SD (US); Matt Buisker, Brookings, SD (US); Jay deBlonk, Brookings, SD (US); Lane A. Munson, Brookings, SD (US); Douglas John Criddle, Brookings, SD (US); Tom Kreutner, Brookings, SD (US); Adam Howard, Brookings, SD (US)

(73) Assignee: Daktronics, Inc., Brookings, SD (US)

(21) Appl. No.: 13/399,149

(22) Filed: Feb. 17, 2012

Related U.S. Application Data
(60) Provisional application No. 61/444,318, filed on Feb. 18, 2011.

(51) Int. Cl. F21V 5/04; F21V 21/00; H05K 7/20; H05K 7/00; G06F 1/16

(52) U.S. Cl. 362/235; 361/679.01; 361/679.21; 361/692; 362/249.02

(57) ABSTRACT

An apparatus includes a first electronic display, a second electronic display generally parallel to and facing away from the first electronic display, and a bracket. The first electronic display is mounted to a first side of the bracket and the second electronic display is mounted to a second side of the bracket. The bracket is dimensioned to extend across a width of a top arm of a basketball hoop stanchion such that the first electronic display at least partially covers a first side of the top arm and the second electronic display at least partially covers a second side of the top arm.

### CLAIM OF PRIORITY

This non-provisional patent application claims the benefit of priority under 35 U.S.C. §119(e) to U.S. Provisional Patent Application Ser. No. 61/444,318, entitled “ELECTRONIC DISPLAY” (Attorney Docket No. 339. 172PRV), filed on Feb. 18, 2011, which is hereby incorporated by reference in its entirety.

### BACKGROUND

The present application relates to displays, and, more particularly, to an electronic display that can be coupled to a support member, such as a basketball stanchion. The present application also relates to diffuser lenses for an electronic display.

Electronic displays are used at sporting events and other venues to provide information or advertising to patrons of the event. Electronic displays are typically mounted to supporting structures such as walls or rafters. In view of utilizing other possible locations for electronic displays, aesthetic and safety concerns should be considered. For example, electronic displays are typically positioned at locations that are not within the view of a broadcast television camera, such as suspended above a basketball court. However, when electronic displays are utilized at locations that fall within the view of a broadcast television camera, the appearance of the display to a viewer of the televised event becomes important. Although the display may appear visually appealing to patrons at the venue, the display may appear distorted to viewers watching the event on television.

### Overview

This overview is intended to provide an overview of subject matter of the present patent application. It is not intended to provide an exclusive or exhaustive explanation of the invention. The detailed description is included to provide further information about the present patent application.

In an example, a display apparatus is provided that includes a first electronic display, a second electronic display generally parallel to and facing away from the first electronic display, and a bracket. The first electronic display is mounted to a first side of the bracket and the second electronic display is mounted to a second side of the bracket. The bracket is dimensioned to extend across a width of a top arm of a basketball hoop stanchion such that the first electronic display at least partially covers a first side of the top arm and the second electronic display at least partially covers a second side of the top arm.

In an example, a display apparatus is provided that includes an LED electronic display having a plurality of LEDs and a diffuser lens positionable over the LED electronic display. The diffuser lens is operable to reduce a moiré effect of the LED electronic display.

In an example, a display apparatus is provided that includes a first electronic display having a plurality of LEDs, a second electronic display parallel to and facing away from the first electronic display, wherein the second electronic display also includes a plurality of LEDs, and a bracket for mounting the first and second electronic displays. Particularly, the first electronic display is mounted to a first side of the bracket and the second electronic display is mounted to a second side of the bracket. The bracket is dimensioned to extend across a width of a top arm of a stanchion such that the first electronic display at least partially covers a first side of the top arm and the second electronic display at least partially covers a second side of the top arm. The display apparatus further includes a first diffuser lens located over the plurality of LEDs of the first electronic display and a second diffuser lens located over the plurality of LEDs of the second electronic display.

These examples can be combined in any permutation or combination.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 illustrates a first side view of an electronic display in accordance with an example of the present patent application, positioned on a basketball stanchion.

FIG. 2 illustrates a second side view of the electronic display of FIG. 1.

FIG. 3 illustrates a perspective view of the electronic display of FIG. 1.

FIG. 4 illustrates a perspective view of the electronic display with a plurality of electronic display panels removed, in accordance with an example of the present patent application.

FIG. 5 illustrates a side view of the electronic display of FIG. 4 with the electronic display panels removed.

FIG. 6 illustrates a top view of the electronic display of FIG. 1.

FIG. 7 illustrates an end view of the electronic display of FIG. 1.

FIG. 8 illustrates an exploded perspective view of an electronic display in accordance with an example of the present patent application.

FIG. 9 illustrates an assembled perspective view of the electronic display of FIG. 8.

FIG. 10 illustrates an exploded perspective view of an electronic display panel module, in accordance with an example of the present patent application.

FIG. 11 illustrates a top, assembled view of the electronic display panel module of FIG. 10.

FIG. 12 illustrates a top view of a diffuser lens, in accordance with an example of the present patent application.

FIG. 13 illustrates a front view of the diffuser lens of FIG. 12.

FIG. 14 illustrates a rear view of the diffuser lens of FIG. 12.

FIG. 15 illustrates a side view of the diffuser lens of FIG. 12.

FIG. 16 illustrates a cross-sectional side view of the diffuser lens of FIG. 12.

FIG. 17 illustrates an exploded perspective view of a modular LED panel and a modular diffuser lens.

### DETAILED DESCRIPTION

The present patent application relates to electronic displays that are adapted for positioning on a support structure, such as a basketball stanchion. In an example, the electronic display can include first and second electronic display panels coupled to a mounting bracket in a spaced apart manner such that the display panels are generally parallel to each other. The present patent application further relates to a diffuser lens for an electronic display panel that helps to reduce or eliminate a moiré patterning when the electronic display panel is viewed through a broadcast television camera.

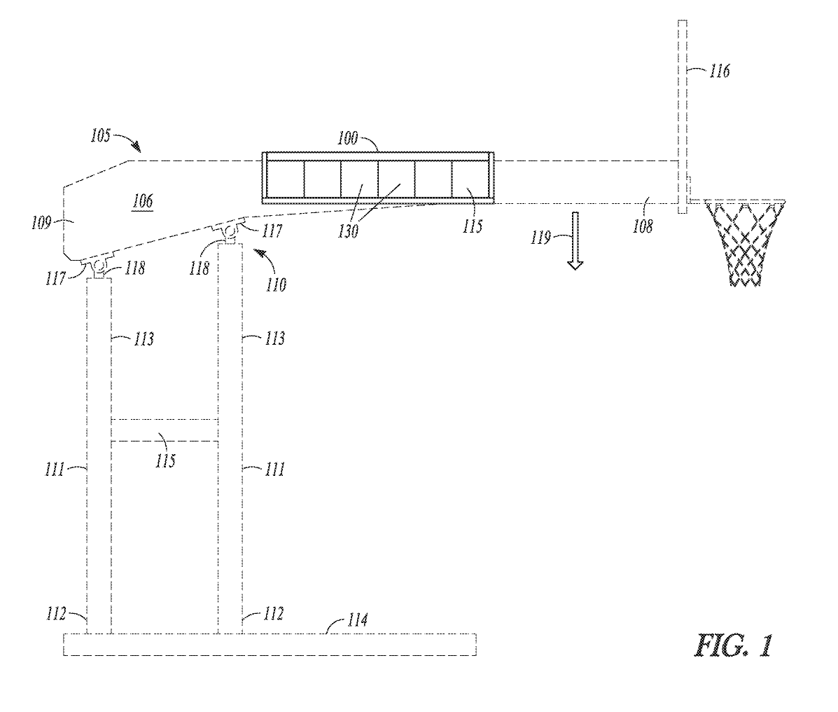

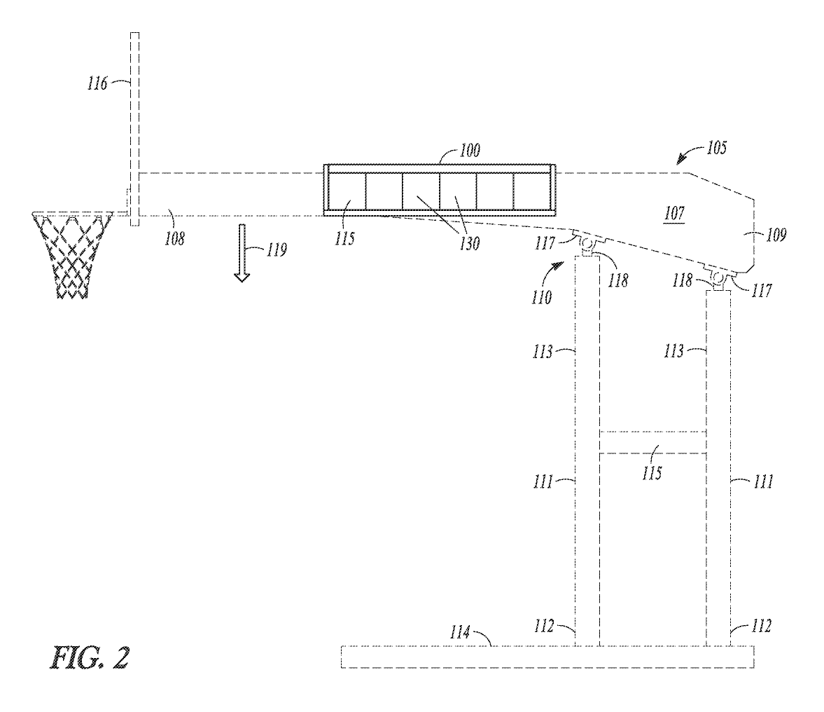

FIGS. 1 and 2 illustrate an example of an electronic display 100 in accordance with the present patent application. Particularly, FIG. 1 illustrates a view of the electronic display 100 from a first side of a basketball stanchion 110 and FIG. 2 illustrates a view from the other side of the basketball stanchion 110. Although the present patent application describes the electronic display 100 as being coupled to a basketball stanchion 110, the electronic display 100 can be configured for attachment to any suitable support structure. Thus, basketball stanchions are described merely for purposes of example and not limitation.

As illustrated in FIGS. 1 and 2, the basketball stanchion 110 can generally include a top arm 105 having a first end 1108 and a second end 109, one or more support posts 111 each having a first end 112 and a second end 113, and a base member 114 structured for positioning on a floor or other support surface. As will be discussed in further detail below, the electronic display 100 can be mounted to the top arm 105 of the basketball stanchion 110. In an example, and as illustrated in FIGS. 1 and 2, the first arm 105 and the base member 114 can extend in a generally horizontal direction and the one or more support posts 111 can extend in a generally vertical direction. However, other configurations are also contemplated. When two or more support posts 111 are utilized as illustrated in FIGS. 1 and 2, one or more bracing members 115 can also be positioned between adjacent support posts 111 to provide increased rigidity of the basketball stanchion 110.

As generally illustrated in FIGS. 1 and 2, the top arm 105 can include a basketball goal 116 secured to the first end 108. The first end 112 of each of the support posts 111 can be fixedly coupled to the base member 114 via a suitable connection means, such as a plurality of bolts or the like. As further illustrated in FIGS. 1 and 2, the first end 109 of the top arm 105 can be pivotally coupled to the second end 113 of each of the support posts 111 via a suitable pivotal connection member 117. In an example, the pivotal connection members 117 can include hydraulic pistons 118 extending into an interior of the support posts 111 that allow a limited amount of movement of the top arm 105 in the direction indicated by arrow 119, such as when a player “dunks” a basketball and applies a downward force on the basketball goal 116.

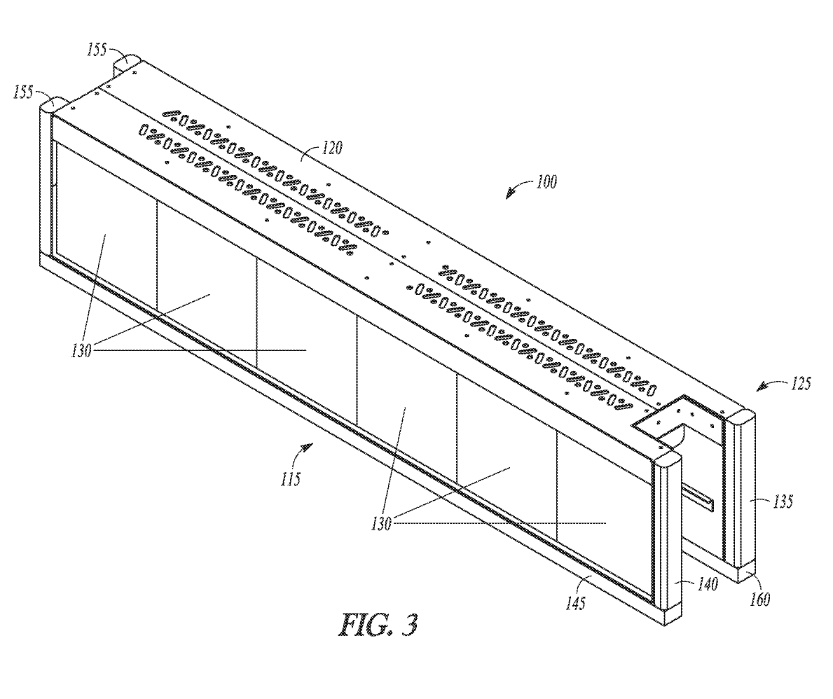

Turning next to FIG. 3, a perspective view of the electronic display 100 is shown removed and isolated from the basketball stanchion 110. In an example, the electronic display 100 can generally include a first electronic display panel 115, such as an LED display panel, which is positioned so that it can at least partially cover a first side 106 of the top arm 105 of the basketball stanchion 110 as illustrated in FIG. 1. The electronic display 100 can further include a second electronic display panel 125 that is generally parallel to and facing away from the first electronic display panel 115 and is positioned so that it can at least partially cover a second side 107 of the top arm 105 of the basketball stanchion 110, as illustrated in FIG. 7.

In an example, each of the first and second electronic displays panels 115, 125 can be mounted to a bracket 120, with the first electronic display panel 115 mounted to one side of the bracket 120 and the second electronic display panel 125 mounted to the opposing side of the bracket 120. Further, the bracket 120 can be dimensioned to extend across the width of the top arm 105 of the stanchion 110 such that the first electronic display panel 115 is positionable on the first side 106 of the top arm 105 and the second electronic display panel 125 is positionable on the second side 107 of the top arm 105.

In an example, the bracket 120 can have a generally “U-shaped” cross-sectional configuration resembling a horseshoe. Particularly, the horseshoe-shaped bracket 120 can include first and second generally parallel sides and a top panel that is generally perpendicular to the first and second sides, thereby defining three sides of a rectangle. The horseshoe-shaped bracket 120 can allow the electronic display 100 to straddle the top arm 105 of the basketball stanchion 110, which in turn can allow the electronic display 100 to sit lower on the basketball stanchion 110.

A horseshoe-shaped bracket 120 defined by a series of parallel and perpendicular sides is described merely for purposes of example and not limitation, and the particular cross-sectional shape of the bracket 120 that is required for a given application may depend on the cross-sectional shape of the top arm 105 of the basketball stanchion 110. For example, a horseshoe-shaped bracket 120 can be suitable for a top arm 105 having a cross-section in the shape of a square or rectangle. However, a top arm 105 having rounded or angled surfaces may require an alternative bracket design that can mate with such surfaces. Thus, in various examples, the bracket 120 can have other suitable cross-sectional shapes without departing from the spirit and scope of the present patent application.

In the example set forth in FIG. 3, each of the first and second electronic display panels 115 and 125 can include a plurality of separate display panel modules 130. With reference to FIGS. 1-3, each of the electronic display panels 115 and 125 includes six separate display panel modules 130 arranged adjacent to one another in a horizontal row. In various examples, a larger or smaller number of display panel modules 130 can be used. Further, each of the electronic display panels 115 and 125 can include display panel modules that are arranged adjacent to one another in a plurality of horizontal rows, thereby defining a matrix of display panel modules 130 arranged in a plurality of horizontal rows and vertical columns. In another example, the first and second electronic display panels 115 and 125 can comprise a single display panel module 130.

With further reference to FIG. 3, the bracket 120 can include one or more pads 135, 140, 145, 150, 155, 160 mounted to and extending along one or more sides and/or edges of the electronic display 100. In an example, the pads 135, 140, 145, 150, 155, 160 can be made from vinyl covered foam. However, any suitable padding material and covering can be used. The pads 135, 140, 145, 150, 155, 160 can supplement the pads in conventional basketball stanchions that are used for player protection during a game.

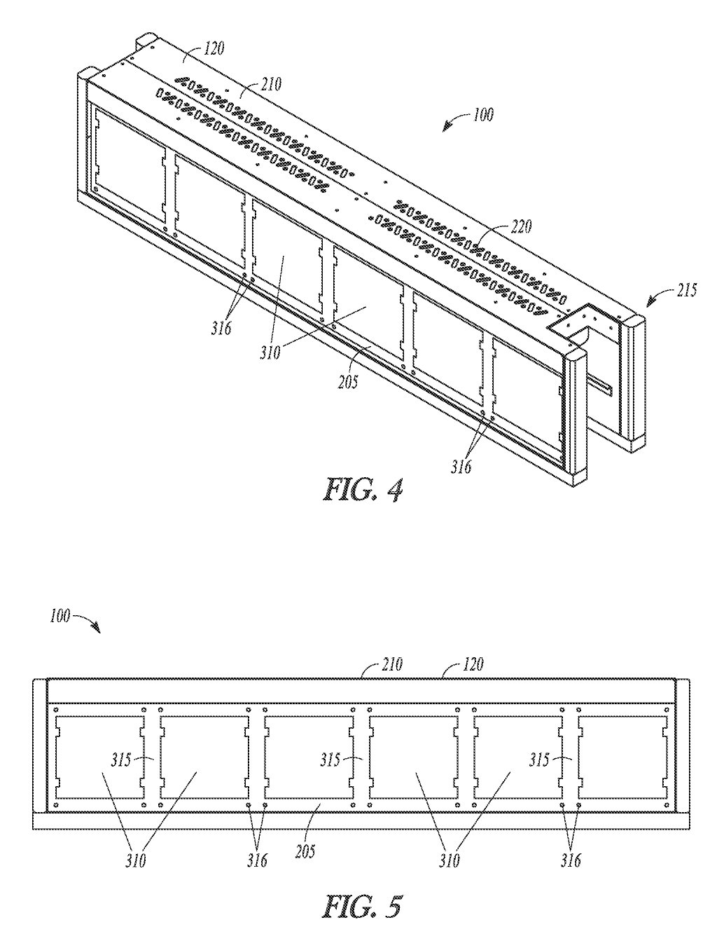

FIGS. 4 and 5 illustrate perspective and side views, respectively, of the electronic display 100 with the electronic display panels 115, 125 removed for clarity. In an example as set forth in FIGS. 4 and 5, the bracket 120 can include a top wall 210 extending between a first side wall 205 and a second side wall 215. Further, each of the first side wall 205 and the second side wall 215 can include a series of openings 310 separated by ribs 315. With reference again to FIG. 3, each of the openings in the first side wall 205 and the second side wall 215 can be sized and dimensioned to receive one of the electronic display panel modules 130 such that the display panel modules 130 are centered over a given opening 310. The electronic display panel modules 130 can be mounted to the first and second side walls 205 and 215 with any suitable connection means. In an example, the electronic display panel modules 130 can be secured with one or more fastening members (not shown) that are configured to be received within fastening apertures 316. The fastening apertures 316 can be, for example, threaded apertures that are structured to receive a threaded screw or bolt member. In another example, the fastening apertures 316 can be non-threaded openings that are structured to receive an expandable pin or bolt, wherein a portion of the pin or bolt expands behind the side wall to retain the electronic display panel module 130 in the opening 310. In yet another example, the electronic display panel modules 130 can be retained in the openings 310 using a suitable clip member.

With reference again to FIG. 4, the top wall 210 can include a plurality of ventilation holes 220 extending from an inner surface to an outer surface of the top wall 210. The ventilation holes 220 allow for the removal of heat generated within the electronic display 100, and thus can increase the life span of the electronic display 100. The size and location of the ventilation holes 220 can depend on numerous factors, such as the amount of heat generated by the electronic display 100, the size of the electronic display 100, or the like.

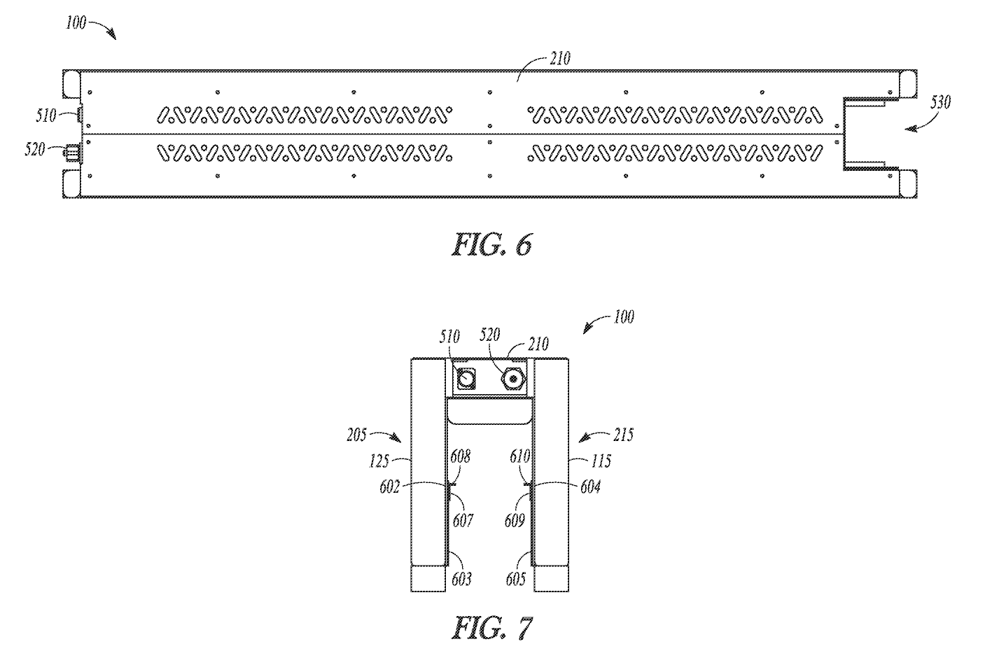

FIGS. 6 and 7 illustrate top and end views, respectively, of the electronic display 100. In operation, the first and second electronic display panels 115 and 125 can be configured to display information for viewers of the electronic display 100. In order to provide power for the device and receive the information to be displayed, the electronic display 100 can include one or more power and/or communication inputs operably coupled thereto. In an example, the electronic display 100 can include a first input 510 to receive power for the electronic display panels 130 and a second input 520 to receive data information signals that contain the information to be displayed on each of the electronic display panels 115 and 125. In various examples, the electronic display 100 can also include one or more outputs for sending data information signals to an external device, such as an electronic display control system.

Alternatively or in addition to providing inputs for receiving and/or sending data information signals, such as the second input 520, a wireless communication means can be incorporated into the electronic display 100 to allow receiving and sending of data information signals without the need for wiring cables to physical input terminals. In an example, the wireless communication can utilize one of the IEEE 802.11 protocols. However, any suitable wireless technology can be utilized including, but not limited to, Bluetooth, ultra-wideband (UWB), wireless USB (WUSB), cellular, or the like.

With further reference to FIG. 6, the top wall 210 of the electronic display 100 can further include a “U-shaped” cut-out portion 530 in one of the ends. This cut-out portion 530 can provide a mounting area for certain basketball stanchion designs. In various examples, the cut-out portion 530 can be omitted.

With reference now to FIG. 7, the electronic display 100 can further include a first clamp member 602 positioned on a first inside surface 603 of the first bracket side wall 205 and a second clamp member 604 positioned on a second inside surface 605 of the second bracket side wall 215. In an example, the first and second clamp members 602 and 604 can be “angle iron” members that extend along at least a portion of the longitudinal length of the electronic display 100. The first clamp member 602 can include first segment 607 secured to the first inside surface 603 and a second segment 608 extending generally perpendicular to the first segment 607. Similarly, the second clamp member 604 can include a first segment 609 secured to the second inside surface 605 and a second segment 610 extending generally perpendicular to the first segment 609. In an example, the second segments 608 and 610 of the first and second clamp members 602 and 604, respectively, can be configured to clamp underneath or engage a portion of the stanchion 110. In various examples, the first and second clamp members 602 and 604 can be omitted or replaced with another suitable clamping or connection means.

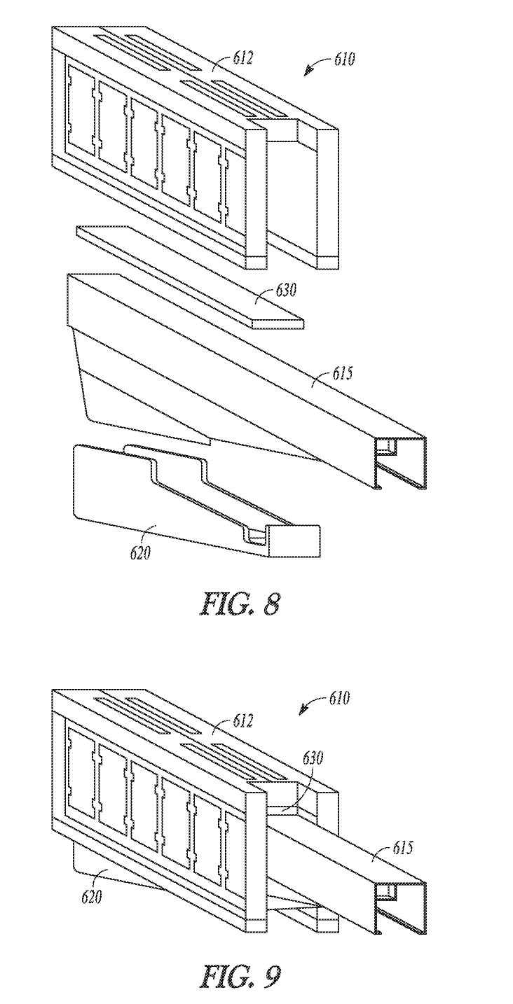

Turning next to FIG. 8, an exploded perspective view of an electronic display 610 in accordance with an example of the present patent application is illustrated. FIG. 9 illustrates a perspective view of the electronic display 610 in an assembled state. The electronic display 610 is similar to the electronic display 100 discussed above, and the previous discussion is therefore incorporated herein by reference. In this example, the first and second inner clamp members 602 and 604 of the electronic display 100 (FIG. 7) have been omitted. With reference to FIGS. 8 and 9, the electronic display 610 can include a top padding member 630 that is sandwiched between a top wall 612 of the electronic display 610 and a basketball stanchion top arm 615. The electronic display 610 can further include a bottom padding member 620 that is configured to mate with a bottom side of the stanchion arm 615. In an example, the bottom padding member 620 can be strapped around the stanchion arm 615, although any suitable connection means can be used such as screws, bolts, pins, clips, or the like. The electronic display 610 can then be secured to the padding member 620. In an example, the padding member 620 can include a wooden backing material, and the electronic display 610 can be attached to the wooden backing material using screws or the like.

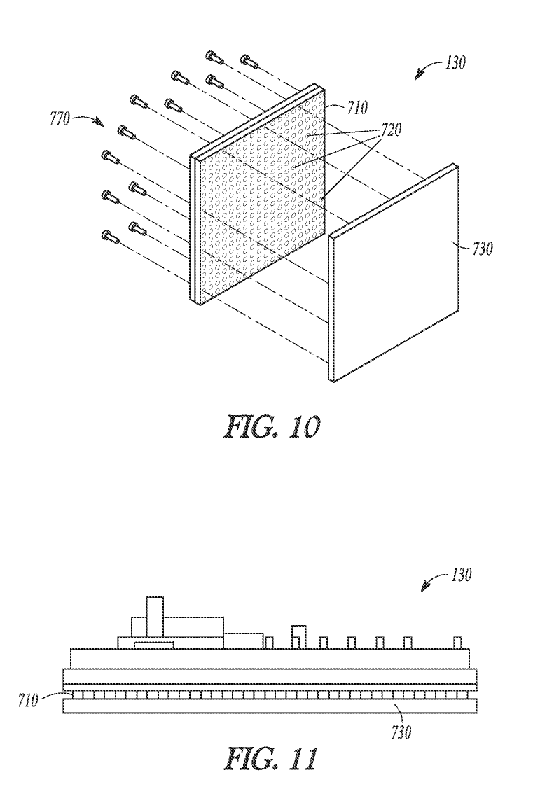

FIG. 10 illustrates an exploded perspective view of the electronic display panel module 130 described above with reference to FIGS. 1-3. FIG. 11 illustrates a top, assembled view of the electronic display panel module 130. In an example, the electronic display panel module 130 can include an LED panel 710 having a plurality of LEDs 720 arranged thereon. The plurality of LEDs 720 can further be grouped into LED pixel units including, for example, one green LED, one red LED, and one blue LED. In an example, the plurality of LEDs 720 or LED pixel units can be formed into a grid pattern. However, any suitable pattern can be used including, for example, an interleaved pattern. The electronic display panel module 130 can further include a diffuser lens 730 positionable over the LED panel 710. In an example, the diffuser lens 730 can be configured to reduce a moiré effect of the LED panel 710. Particularly, many electronic LED displays reveal a moiré patterning effect when the display is viewed through a broadcast television camera. The moiré patterning can occur when there is a mismatch between the grid pattern of the LED panel 710, where the individual LEDs or LED pixel units are generally arranged in a spaced apart manner, and the grid pattern of the charge coupled device (CCD) in the broadcast television camera. Whenever the grid pattern on the display and the grid pattern on the camera CCD have frequencies that do not match each other, a moiré pattern occurs. The diffuser lens 730 in accordance with the present patent application can help to reduce or eliminate the moiré patterning when showing an electronic LED display on a broadcast television camera by masking the grid patterning of the LED panel 710.

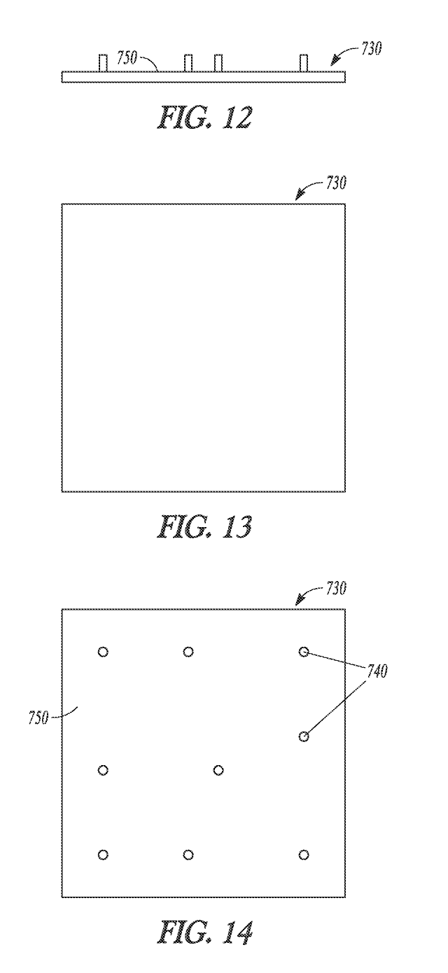

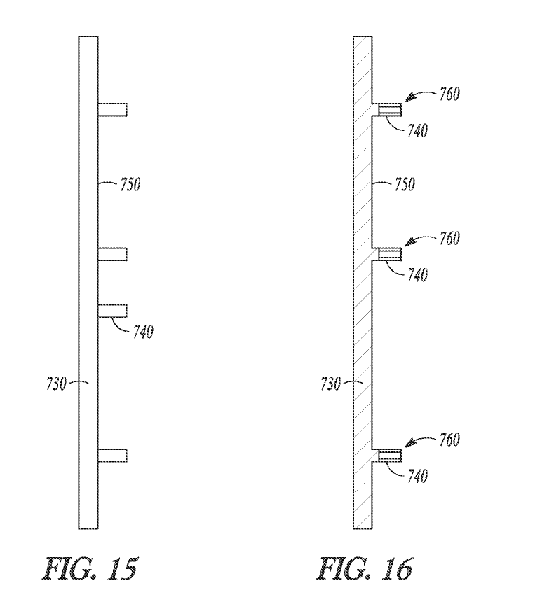

FIGS. 12-15 illustrate top, front, rear, and side views, respectively, of the diffuser lens 730 described above with reference to FIGS. 10 and 11. FIG. 16 illustrates a cross-sectional side view of the diffuser lens 730.

With particular reference to FIGS. 12 and 14-16, the diffuser lens 730 can include a plurality of mounting posts 740 extending from a back surface 750 of the diffuser lens 730. The mounting posts 740 can be sized and dimensioned to be received within a corresponding plurality of mounting post receptacles (not shown) in the LED panel 710 to secure the diffuser lens 730 to the panel 710. As illustrated in the cross-sectional view of FIG. 16, each of the mounting posts 740 can include a receptacle 760 that is configured to receive a fastening member 770 (FIG. 10) to secure the LED panel 710 and the diffuser lens 730 together.

In an example, the mounting posts 740 can be positioned in a symmetrical or grid-like pattern. In another example, as illustrated in FIG. 14, the mounting posts 740 can have an offset pattern. The offset pattern of the mounting posts 740 can act as a keying feature to prevent the diffuser lens 730 from being assembled to the LED panel 710 in an improper orientation.

In various examples, the diffuser tens 730 can be designed as a single, continuous element or as a plurality of modular elements. Some display panel modules use a single LED panel, and in those instances, a single diffuser lens having a size commensurate with that of the LED panel may be preferable. However, since many display panels are modular and can be built into a display having any ratio and size by building the LED panels up in both a vertical and a horizontal direction, it can be impractical to have the diffuser lens created as a single piece to cover the entire display.

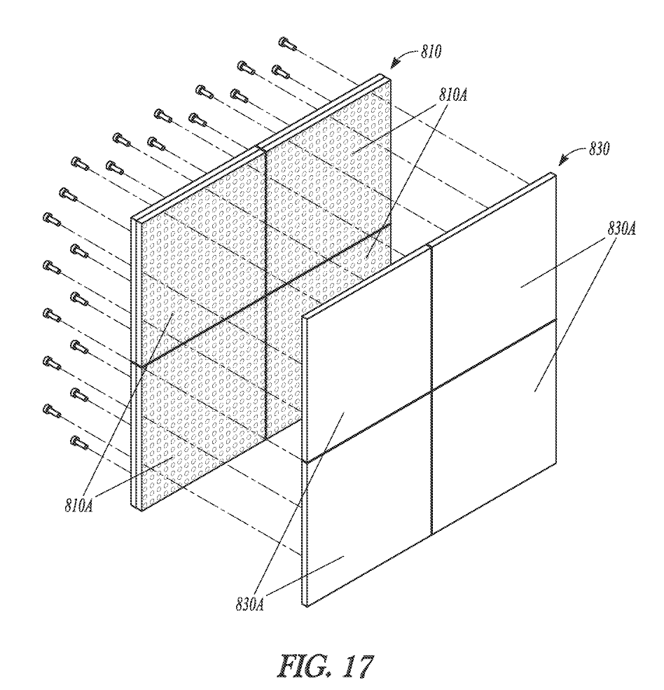

FIG. 17 is an exploded perspective view of an electronic display panel module 230 including a modular LED panel 810 and a modular diffuser lens 830. As illustrated in FIG. 17, the modular LED panel 810 can include a plurality of adjacently positioned LED panels 810A, and the modular diffuser lens 830 can include a corresponding plurality of adjacently positioned diffuser lenses 830A that are configured to align with the LED panels 810A. Therefore, in an example, each diffuser lens 830A can be sized and dimensioned such that it covers a single LED panel 810A, thereby providing greater flexibility when constructing a “filtered” electronic display panel module.

Now that the function of the diffuser lenses in accordance with the present patent application has been described, along with their physical assembly into an electronic display panel module, various examples of diffuser lens properties will be discussed in detail.

In an example, the diffuser lenses can include a plastic material and a diffusing agent. The diffusing agent can be in the form of an external diffusion film that can be applied to a lens made from the plastic material. Alternatively, the plastic material, along with the diffusing agent, can be injected into a filter lens mold and molded into a diffuser lens configuration. In certain examples, sheet extrusion molding can be used. One benefit of molding the plastic material and the diffusing agent together into a single-component lens configuration is the elimination of the external film layer that would otherwise be required in order to create the diffusion effect.

Any transparent thermoplastic material can be used for manufacturing the diffuser lenses. Examples of suitable plastics include, but are not limited to, polymethyl methacrylate plastic, strength-modified polymethyl methacrylate, polycarbonate plastic, polystyrene plastic, styrene-acrylic-nitrite plastic, polyethylene terephthalate plastic, glycol-modified polyethylene terephthalate plastic, polyvinyl chloride plastic, transparent polyolefin plastic, acrylonitrile-butadiene-styrene (ABS) plastic or mixtures (i.e., blends) of various thermoplastics.

In various examples, inorganic pigments can be used as the diffusing agent. One example of an inorganic pigment that can be used as the diffusing agent is an ultramarine blue pigment. However, any suitably colored inorganic pigment can be used that provides a sufficient amount of diffusion.

Alternatively or additionally, the plastic material can also include one or more tinting agents. Examples of tinting agents can include, but are not limited to, carbon black pigments and iron oxide pigments. In an example, the iron oxide pigments can be iron oxide black. The tinting agent, which can be added to the plastic material prior to the molding step, helps maintain a level of acceptable contrast to the diffuser lens as the diffusion material by itself tends to have a milky whitish appearance, which can decrease the visual contrast of the electronic display.

In another example, the diffuser lenses can be made of various polymers such as, for example, a polymer selected from the line of Acrylite® df light diffusing molding and extrusion compounds manufactured by Evonik Cyro LLC of Parsippany, N.J. Acrylite® df light diffusing molding and extrusion compounds are acrylic polymers with superior light diffusion and transmittance properties, which can result in higher light intensity and output ratio compared to conventional pigment-diffusion polymers. In an example, this type of material can offer increased lighting efficiency with a 20-40% increase in light transmittance versus pigmented products. The special optical properties can be obtained by incorporating spherical, high molecular weight polymer beads with a different refractive index into the acrylic matrix. The difference in refractive indices can change the direction of light travel within the diffuser lens, with the net result being a substantially even distribution of light exiting the LEDs.

In an example, the Acrylite® df light diffusing molding and extrusion compound can be injection molded into a lens configuration, which may or may not be pigmented. Impact modifiers can be added to the injection mold to improve the brittleness and impact resistance. Acrylite® df light diffusing molding and extrusion compounds exhibit very minimal, if any, color shift when viewed from the side and have a low contrast with respect to their background compared to traditional light diffusers.

The various light diffuser lens materials described above were presented merely for purposes of example and not limitation. Thus, other light diffuser lens materials having similar properties can be used without departing from the spirit and scope of the present patent application.

In an example, the diffuser lenses can have one or more textured surfaces to help diffuse the light hitting the front of the diffuser lens, which can help reduce or eliminate “hot spots.” Providing a diffuser lens with a textured surface can be useful since a non-textured plastic or polymeric piece tends to reflect light thereby creating hot spots from overhead lighting and indirect lighting sources when viewed from certain angles. In an example, the textured diffuser lens can be formed in a mold having a bead blasted texture, which creates a roughened surface contour as the lens material cures within the mold. Alternatively or additionally, acid etching can be used to provide the textured lens surface.

Diffuser lenses in accordance with the present patent application can have any suitable lens thickness. In an example, the diffuser lenses can have a thickness in a range from about 1 mm to about 4 mm. However, diffuser tenses having a greater thickness are also contemplated. In an example, the thickness of the diffuser lens can be selected so as to allow for receipt of the maximum benefit of the diffused material while maintaining crispness of the displayed image. Particularly, if the LED pixels were to be over-diffused, the overall image would have a soft, out of focus appearance. Thus, selection of the proper diffuser lens thickness can be an important factor in the overall quality of the displayed image.

The above detailed description includes references to the accompanying drawings, which form a part of the detailed description. The drawings show, by way of illustration, specific embodiments in which the subject matter of the present patent application can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof shown or described herein.

All publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein,” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Although the subject matter of the present patent application has been described with reference to various embodiments, workers skilled in the art will recognize that changes can be made in form and detail without departing from the scope of the present patent application recited in the below claims.

What is claimed is:

1. An apparatus comprising:
a first electronic display;
a second electronic display generally parallel to and facing away from the first electronic display; and
a bracket, wherein the first electronic display is disposed on a first side of the bracket and the second electronic display is disposed on a second side of the bracket, wherein the bracket is dimensioned to extend across a width of a top arm of a basketball hoop stanchion such that the first electronic display at least partially covers a first side of the top arm and the second electronic display at least partially covers a second side of the top arm.

2. The apparatus of claim 1, wherein the first electronic display and the second electronic display each include a plurality of LED panels.

3. The apparatus of claim 1, wherein the bracket includes an input to receive power for the first and second electronic displays.

4. The apparatus of claim 3, wherein the bracket includes an input to receive data information to display on each of the first and second electronic displays.

5. The apparatus of claim 1, wherein the first electronic display is mounted to a first side wall of the bracket and the second electronic display is mounted to a second side wall of the bracket.

6. The apparatus of claim 5, wherein the bracket further includes a top wall extending between the first side wall and the second side wall.

7. The apparatus of claim 6, wherein the top wall includes a plurality of ventilation holes.

8. The apparatus of claim 6, further comprising one or more pad members positioned along one or more edges of the first and second side walls.

9. The apparatus of claim 1, wherein the bracket is a horseshoe-shaped bracket.

10. An apparatus comprising:
an LED electronic display including a plurality of LEDs; and
a diffuser lens positionable over and coupleable to the LED electronic display, the diffuser lens operable to reduce a moiré effect of the LED electronic display.

11. The apparatus of claim 10, wherein the diffuser lens includes one or more textured surfaces.

12. The apparatus of claim 10, further comprising a plurality of mounting posts extending from a back surface of the diffuser lens that are structured to be received within a corresponding plurality of mounting post receptacles in the LED electronic display to secure the diffuser lens to the LED electronic display.

13. The apparatus of claim 12, wherein the mounting posts are arranged in an offset pattern to prevent the diffuser lens from being coupled to the LED electronic display in an improper orientation.

14. The apparatus of claim 13, wherein each of the mounting posts includes a fastener receptacle for receiving a fastener that is insertable from a back side of the LED electronic display.

15. The apparatus of claim 10, wherein the diffuser lens is formed from a plastic material.

16. The apparatus of claim 15, wherein the plastic material includes an inorganic pigment.

17. The apparatus of claim 15, wherein the plastic material includes a tinting agent.

18. The apparatus of claim 10, wherein the diffuser lens is formed from an acrylic polymer.

19. The apparatus of claim 10, wherein the LED electronic display comprises two or more stacked modular LED panels.

20. The apparatus of claim 19, wherein the diffuser lens comprises two or more stacked modular diffuser lens panels that align with the stacked modular LED panels.

21. An apparatus comprising:
a first electronic display including a plurality of LEDs;
a second electronic display generally parallel to and facing away from the first electronic display, the second electronic display also including a plurality of LEDs; and
a bracket, wherein the first electronic display is mounted to a first side of the bracket and the second electronic display is mounted to a second side of the bracket, and wherein the bracket is dimensioned to extend across a width of a top arm of a stanchion such that the first electronic display at least partially covers a first side of the top arm and the second electronic display at least partially covers a second side of the top arm;
a first diffuser lens located over the plurality of LEDs of the first electronic display; and
a second diffuser lens located over the plurality of LEDs of the second electronic display.

22. The apparatus of claim 21, wherein the first and second diffuser lenses are formed from a plastic material.

23. The apparatus of claim 22, wherein the plastic material includes an inorganic pigment.

24. The apparatus of claim 23, wherein the inorganic pigment is ultramarine blue.

25. The apparatus of claim 22, wherein the plastic material includes a tinting agent.

26. The apparatus of claim 25, wherein the tinting agent is iron oxide black.

27. The apparatus of claim 25, wherein the tinting agent is carbon black.

28. The apparatus of claim 21, wherein the first and second diffuser lenses each include one or more textured surfaces.

29. The apparatus of claim 21, wherein the first and second diffuser lenses each have a thickness in a range between about 1 mm and about 4 mm.

30. The apparatus of claim 21, wherein the first and second electronic displays each comprise a plurality of modular display panels.

31. The apparatus of claim 30, wherein the first and second diffuser lenses each comprise a plurality of modular diffuser tens panels.

32. The apparatus of claim 21, wherein the first and second diffuser lenses each include a plurality of offset mounting posts that are receivable within mounting post receptacles in the corresponding first and second electronic displays.
